(19) United States
(12) Patent Application Publication
(10) Pub. No.: US 2007/0031991 A1
(43) Pub. Date: Feb. 8, 2007

(54) Method for depositing compounds on a substrate by means of metalorganic chemical vapor deposition

(75) Inventors: Hilde Hardtdegen, Aahen (DE); Roland Schmidt, Übach-Palenberg (DE); Nicoleta Kaluza, Mönchengladbach (DE); Konrad Wirtz, Baesweiler (DE); Yuri Makarov, Erlangen (DE)

Correspondence Address: THE FIRM OF KARL F ROSS, 5676 RIVERDALE AVENUE, PO BOX 900, RIVERDALE (BRONX), NY, 10471-0900, US

(73) Assignee: FORSCHUNGSZENTRUM JULICH GMBH, Julich (DE)

(21) Appl. No.: 10/550,365

(22) PCT Filed: Feb. 20, 2004
(86) PCT No.: PCT/DE04/00315

§ 371 Date: Jun. 14, 2006

(30) Foreign Application Priority Data
Mar. 21, 2003 (DE) 103 12 768.2
Jun. 6, 2003 (DE) 103 25 629.6

(51) Int. Cl. H01L 21/365; C23C 16/00

(52) U.S. Cl. 438/102; 438/104; 438/483; 438/785; 118/715

(57) ABSTRACT

The invention relates to a method for depositing compounds on a substrate by means of metalorganic chemical vapor deposition and a first mixture comprising at least one carrier gas and at least one organometallic compound as well as a second mixture comprising at least one carrier gas and at least one group V compound or group VI compound, both mixtures being separately fed into an MOCVD system. According to the invention, the first mixture comprising at least one carrier gas and at least one organometallic compound is directed into the system between the substrate and the second mixture comprising at least one carrier gas and at least one group V compound or group VI compound, which has the advantageous effect of creating no parasitic deposits on the walls of the MOCVD system. Hence, the deposition rates are increased compared with methods known in prior art.

The invention relates to a method of depositing compounds on a substrate by means of metal organic gas-phase deposition.

Metal-organic gas-phase deposition (metal-organic chemical vapor deposition (MOCVD) is a method of making layer structures of a complex configuration as can be used in electronic components, for example, high-speed transistors for Handys or light-emitting diodes. By contrast to known silicon structures, these structures are composed not of one element but from two or even more elements. They can be referred to therefore also as compound semiconductors. The metal organic gas-phase deposition is carried out in a so-called MOCVD apparatus.

With the MOCVD apparatus, nitride layers among others can be deposited and can be comprised of two elements, like for example, GaN, InN or AlN or from more elements like for example GaInN or AlGaN. These compounds are referred to as binary or terniary systems for the monocrystalline deposition of nitride compounds, sapphire (Al₂O₃) or silicon carbide (SiC) or silicon, which have similar crystal characterstics to the nitrides are used as substrates.

The group III nitrides include through their representatives a semiconductor system with direct band gaps of 1.9 eV for InN to 6.2 eV for the aluminum nitride AlN.

These nitride layers are economically very significant since they can emit light in the blue part of the visible spectrum upon electrical excitation and thus can be used to make optoelectronic components which are useful in the corresponding energy range. As an example of this are pn light-emitting diodes on the basis of GaN.

For metal organic gas-phase deposition of nitride layers one requires gas-phase compounds of gallium, indium or aluminum as well as NH₃ as so-called precursors. In the case of gallium, a metal organic compound, for example trimethylgallium (TMG) is used. By means of a carrier gas, for example hydrogen, the precursor is carried into a reaction compartment of the apparatus. There is found the substrate, a monocrystalline very thin disk (wafer) which can be heated. The wafer is mounted so as to rotate on a so-called susceptor to produce a uniform distribution of temperature and precursor in the gas phase over the substrate. With an infrared radiator or high-frequency heating the susceptor and the substrate are heated. The temperature of the substrate reaches about 1500° C. depending upon which material systems is deposited. This region is also designated as the hot zone.

For the deposition upon the substrate, the precursor is transformed. This occurs in part already in the gas phase as a result of the heat which is emitted by the substrate or by impingement of molecules of the carrier gas thereon. The molecular fragments deposit upon the substrate surface. As a result of the high temperature the original precursor compounds decompose and react to form new compounds, for example, GaN, InN or AlN. In this manner a new layer grows upon the wafer in atomic layer after atomic layer as GaN, InN or AlN. The residues of the starting molecules, for example methyl groups from TMG and hydrogen combine partly with one another to form methane. Molecules which do not deposit or adhere and molecular fragments are released from the surface and like the methane are carried off with the carrier gas stream and are discharged from the MOCVD apparatus to a gas cleaning system, a so-called scrubber, for removal.

An MOCVD apparatus usually has two gas inlets and provisions for dividing the gas streams which are to be introduced into the apparatus so that an instantaneous mixing within the apparatus which could lead to the formation of acid-based adducts prematurely, can be avoided. For this purpose a partition or separator plate can be so arranged downstream of the gas inlets of the apparatus that the MOCVD apparatus is compartmented into an upper and a lower space. Outside the apparatus, gas supply lines or manifolds are provided which can be connected to supply vessels. In these supply vessels the starting materials are held in readiness, for example on the one hand the metal organics and on the other hand group V or group VI compounds.

A drawback is that up to now it has not been possible to flexibly distribute the gases within the compartments of the apparatus.

In the formation by the aforedescribed technology of, for example, group III nitride layers by means of gas phase deposition in a MOCVD apparatus, precursors together with their carrier gases (H₂, N₂, argon) are each separately fed into the apparatus. The gas streams are first mixed in the hot zone of the apparatus in order to ensure a stable nitride surface at which at the growth temperature nitrogen may be volatile, the carrier gas/NH₃ mixture (Group V compounds) according to the state of the art is locally introduced more closely to the growth surface at the substrate than the carrier gas/metal-organic mixture. As a consequence the hot surface of the substrate will cause nitrogen to be liberated from the ammonia and to be available for reaction upon the substrate. This approach has also been used for the deposition of other compounds as well.

A drawback of this system is that the nitrides which are formed also tend to deposit rapidly parasitically on the hot walls of the apparatus. The nature and thicknesses of these deposits vary in the course of the method. The parasitic deposits cause variations in the growth on the substrate by catalytic decomposition of the starting compound and the reduction in concentration in the gas phase as a result. Since the deposited compounds are of a dark coloration, they influence the gas phase temperature and the surface temperature of the substrate. The nitride layers can thus not be reproducibly formed on the substrate.

The parasitic deposits flake off from the walls after a short time and the particles can then fall from the parasitic-deposit-coated parts of the apparatus upon the substrate or the sample and can have a detrimental effect on the characteristics of the layer or layers to be applied there.

As a solution to this problem, the parts of the apparatus which have been coated by the parasitic deposition and which may come into contact with the substrate, are replaced or cleaned as soon as the parasitic deposit has accomulated to a critical level.

This however is detrimentally expensive since in the interim the apparatus cannot be used.

The object of the invention is to provide a process for depositing a compound on a substrate by means of methyl organic gas-phase deposition without such parasitic deposits occurring.

The object is achieved with a method with the feature of patent claim 1 and with a MOCVD apparatus with the features of patent claim 15. Advantageous features are also given in the patent claims respectively dependent thereon.

According to the invention, in the method a first mixture of at least carrier gas and at least one metal organic compound and a second mixture of at least one carrier gas and at least one Group V compound or Group VI compound are used, whereby both mixtures are separately admitted into an apparatus for depositing the compound upon the substrate. The method is characterized in that at least one metal organic compound is introduced between the substrate and the Group V or Group VI compound. The at least one metal organic compound is thus fed into the apparatus at a location which is closer to the substrate than the Group V or Group VI compound.

Advantageously this has the effect that the thickness of the parasitic deposition is significantly reduced since the deposit is formed practically exclusively where it is desired, namely upon the substrate. The deposition rate as a rule is increased and the coatings or layers are of higher purity by comparison with layers of coating which are deposited by state of art techniques.

The particle formations on the wall and the ceiling of the apparatus are reduced to a minimum. Many layers can be deposited reproducibly before parts coated by parasitic deposition of the apparatus must be replaced in an expensive operation and without the danger that materials separating from parasitic deposits will flake off and contaminate the deposited layer.

The metal organic compound can be selected from a Group II compound or a Group III compound or a Group IV compound. Only examples, barium/strontium compounds (Group II) or trimethylgallium, trimethylaluminum and trimethylindium (Group III) or titanium isopropoxide (Group IV) are specifically mentioned only by way of example. As Group V compounds NH₃ and/or AsH₃ and/or PH₃ can be used and as Group VI compounds, oxygen or diethyltelluride can be used.

It will be self-understood that the method is not limited to a selection from such compounds. Rather the method can basically be used for the deposition of compounds on a substrate by means of metal organic gas-phase deposition generally. As a carrier gas for the compounds, hydrogen and/or nitrogen and/or argon are to be considered.

For the deposition of for example GaN, trimethylgallium is selected as a Group III compound and NH₃ as the Group V compound with hydrogen as the respective carrier gas in each case.

In this case, the metal organic/carrier gas mixture is introduced between the substrate and the point at which the NH₃/carrier gas mixture is introduced. It is however possible without limiting the invention to carry out the process according to the invention with other compounds to avoid parasitic deposition.

An MOCVD apparatus has at least two gas inlets, a first for a first mixture and at least one second for a further mixture. The gases themselves derive from the supply vessels. Between the gas inlets of the apparatus and the supply vessels for the gasses there are, according to the invention, means, especially at least two three-way valves, arranged in so-called gas-collecting lines. There can however also be suitable quick-connect couplings in these lines.

This enables advantageously the apparatus to be connected to the supply vessels and the gases to be flexibly introduced into the various compartments of the MOCVD apparatus in a flexible manner without each time requiring the apparatus to be separated from the supply vessels to be newly connected thereto.

In other words the operator of such an apparatus is able to supply gases based upon his requirements conveniently and flexibly into the parts of the apparatus at which they are required. For this purpose inlets for the gas mixtures can rapidly be exchanged for one another.

It is also conceivable for this purpose to provide other structural modifications to the apparatus.

Below the invention will be described in greater detail b based upon several embodiments or examples and the accompanying 5 Figures.

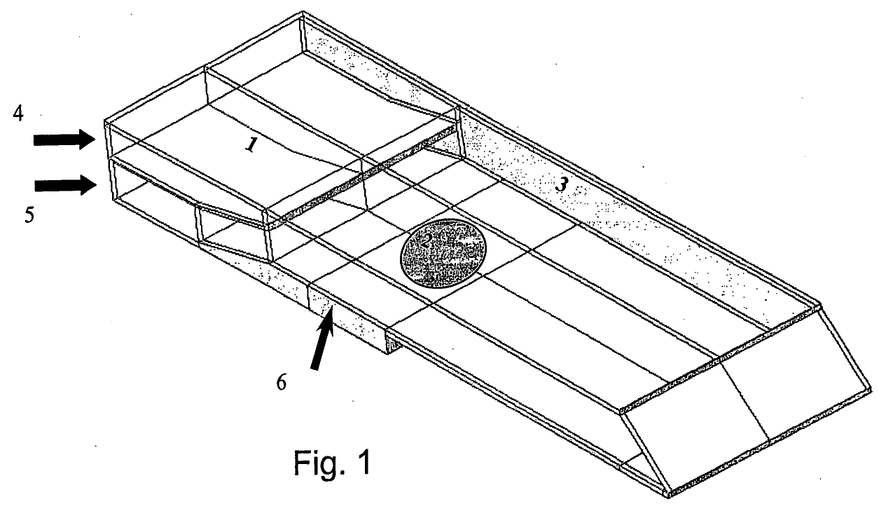

FIG. 1 shows schematically a MOCVD apparatus according to the state of the art with two gas inlets 4, 5 for an upper compartment and a lower compartment. Precursors are separated from one another by partition plate 1 and are supplied to a substrate 2 to be coated. The MOCVD apparatus is compartmented by the partition 1 into an upper chamber and a lower chamber downstream of the gas inlet 4, 5. The substrate 2 can for example be a two unit wafer. Self-understood, moreover, is that the method is not limited to particular sizes or shapes of the substrate. The substrate 2 is mounted in a susceptor 6 which is here formed as a rotatable plate. The walls of the apparatus have only been indicated in the drawing. That is, only one wall has been illustrated substantively, namely the wall 3 in the present case. The front walls in the direction of view of the roof have not been illustrated to allow a look into the interior of the apparatus.

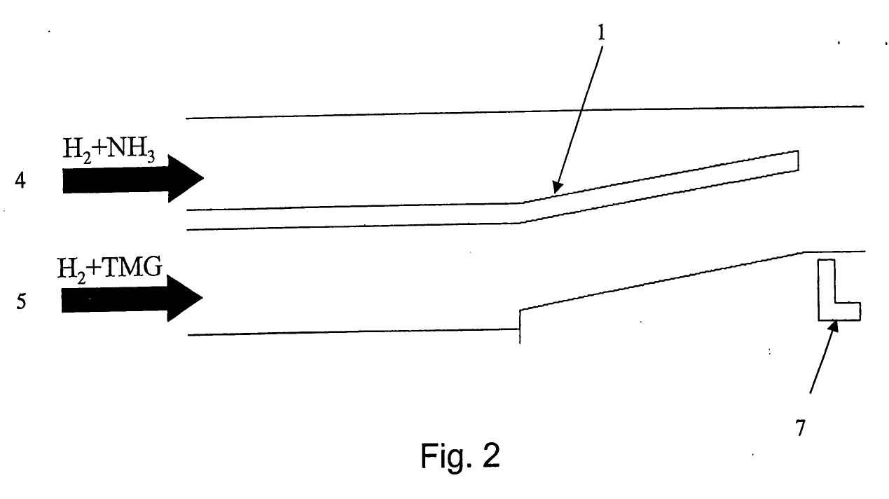

FIG. 2 is a cross section through the apparatus along an imaginary line between the inlets and a cooling unit 7 located upstream of the susceptor (not shown). The cooling unit 7 has been shown only representatively in FIG. 2. In the present case, the gas inlet 5 is provided to introduce the metal organic/carrier gas mixture (TMG/H₂) and the gas inlet 4 for the NH₃/carrier gas mixture (NH₃)/H₂). After the gases are admitted into the apparatus the two gas streams remain separated from one another initially by the partition 1 until they mix downstream of the partition plate 1 and contact the substrate on the susceptor. The metal organic/carrier gas mixture is introduced between the substrate and the NH₃/carrier gas mixture.

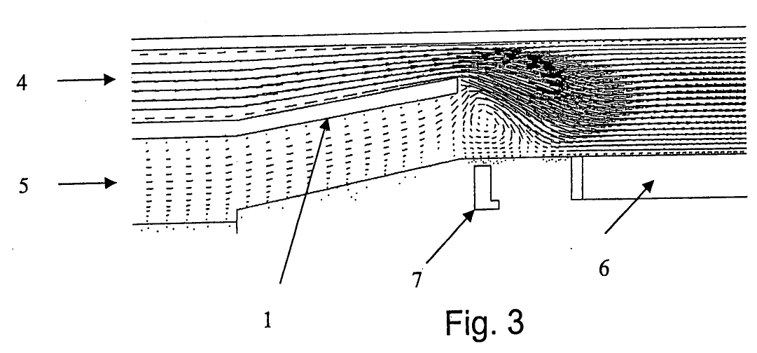

FIG. 3 shows the mixing of the reactants above the cooling unit 7 shown only schematically and shortly ahead of the susceptor 6. The more dense ammonia/carrier gas mixture diffuses in the direction of the substrate on the susceptor 6 where it mixes with the metal organic/carrier gas mixture. On and upstream of the substrate such that the decomposition of the precursor is catalytically accelerated, there is a precipitation of GaN. The total gas mixture does not reach the roof of the apparatus so that there too a parasitic deposition of GaN is avoided.

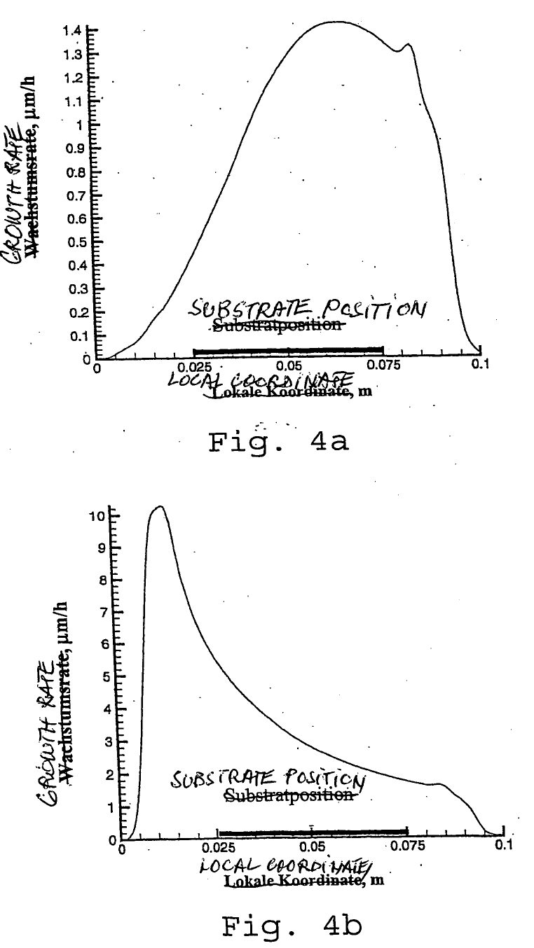

FIG. 4a shows the course of the deposition of GaN as will arise in the state of the art. The X axis shows the local coordinate along a substrate or a wafer. The wafer is represented by the black bar. The deposition rate after an hour amounts to only about 1.3 micrometer GaN.

The process according to the invention, in which the TMG/H₂ mixture is introduced according to the invention between the substrate and the NH₃ carrier gas mixture and thus locally more proximal to the substrate, enables on average a much higher deposition rate of about 4 to 5 micrometers GaN. Because of the rotatable susceptor 6, the deposit can be uniformly distributed across the wafer (FIG. 4b). The higher deposition rate ahead of the wafer enables the deposition of GaN with much higher purity on this wafer.

The higher deposition rate in this latter case is a result of the fact that the gas phase is not diminished as a result of parasitic deposition on the apparatus walls. The gases therefore remain available for the deposition on the substrate.

The deposition illustrated in FIGS. 2-4 of GaN is only given by way of example. As another example of the present invention is the deposition of zinc telluride.

In this case, between the substrate and the Group VI compound diethyltelluride, the Group II compound dimethylzinc is fed into the apparatus.

It is also possible in the deposition of the dielectric (Ba, Sr) titanate, for a mixture of two or three metal organics to be fed between oxygen and the substrate into the apparatus. The metal organics comprise for example a mixture of diketonate of barium and strontium and aloxides of titanium, for example, titanium isopropoxide. Thus between the substrate and the oxygen, of the Group VI compounds, the mixture of these metalorganics is fed into the apparatus.

Furthermore, it is possible to produce respective compounds in layer form each from a suitable combination of metal organics and Group V or Group VI compounds as has been given in Table 1.

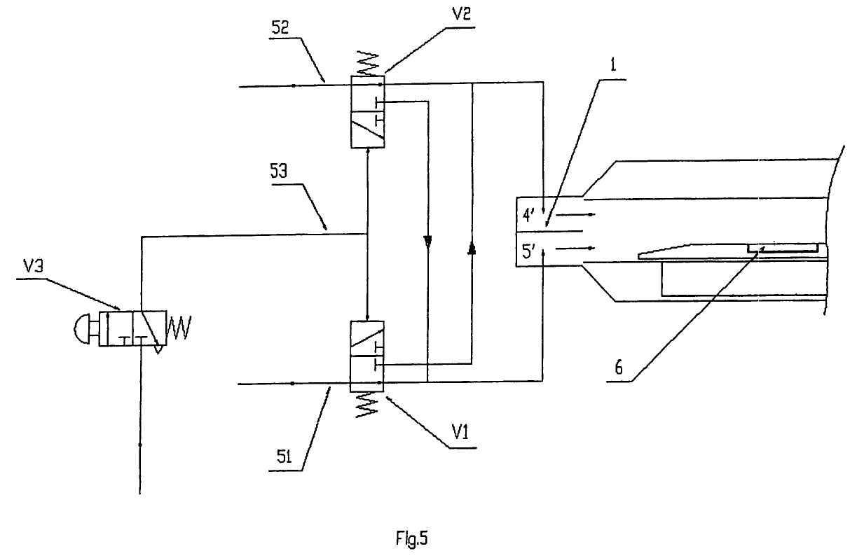

FIG. 5 shows a switching device for the gas inlets of a MOCVD apparatus. The collecting line 52 is connected with a supply vessel (not shown) for a carrier gas/metal organics gas mixture and contains the pneumatic 3/2-way valve V2. The collect line 51 is connected with a supply vessel or carrier gas/Group V or Group VI gas mixture and contains through the pneumatic 3/2-way valves [3 port/2 position valve] V1. The valves V1 and V2 are connected via the respective lines with the upper compartment 4′ and the lower compartment 5′ of the gas inlets. In the pressureless state of valve V2 the valve opens into the upper compartment and the depressurized state of valve V2 the valve opens into the upper compartment and the depressurized state of valve 1, it opens into the lower compartment 5′ (see FIG. 5). The gases are introduced in the state of the art technique into the apparatus.

Both valves V1 and V2 are connected to a N₂ pressure line 53 over a manually-operated valve V3 and can be switched over thereby. In that case, the mixture of the carrier gas or carrier gases and at least one metal organic is then fed under pressure into the compartment 5′ and thus between a substrate on the susceptor 6 and a mixture of carrier gas or gases and at least one Group V or Group VI compound. The last mentioned gas mixture is then fed into the compartment 4′. The partition plate 1 in FIG. 1 has only been shown representationally and extends as shown in FIGS. 1 and 3 up to the susceptor 6. Thus it is ensured that the different gas mixtures will never be present simultaneously in one and the same compartment 4′ and 5′. This kind of improvement enables as reliable and at the same time flexible feed of the gas mixture into the upper and lower compartment 4′, 5′ of the apparatus.

Parts list:

3/2-way valves (V1, V2): ¼ inch VCR-FFF

3/2-way valve (v3) hand-operated, built-in panel valves Bosch) 0820 402 024 3/2 WV NG4 (⅛ inch)

Stainless steel pipe 8/8 inch electropolished

Pneumatic tubing ⅛ inch

TABLE 1

| | | Group V/Group VI | Carrier |
|---|---|---|---|
| Layer Compound | Metal Organic | Compound | Gas |
| Aluminumgalliumarsinide | TMAl(Trimethylaluminum), | AsH₃(Arsine) | H₂, N₂, |
| ((AlGa)As) | TEAl(Triethylaluminum), | TBAs (Tertbutylarsine) | Ar |
| | TMGa(Trimethylgallium), | | |
| | TEGa(Triethylgallium | | |
| Galliumarsenide (GaAs) | TMGa, TEGa | AsH_{3,} TBAs | H_{2,} N_{2,} Ar |
| Aluminumarsenide (AlAs) | TMAl, TEAl | AsH_{3,} TBAs | H_{2,} N_{2,} Ar |
| Galliumindiumarsenide | TMGa, TEGa, TMin | AsH₃, TBAs | H_{2,} N_{2,} Ar |
| (AlIn)As) | | | |
| Aluminumindiumarsenide | TMAl, TEAl, TMln | AsH_{3,} TBAs | H_{2,} N_{2,} Ar |
| ((GaIn)As) | | | |
| Indiumphosphide | TMln | PH_{3,}, TBP | H_{2,}, N_{2,} |
| (InP) | | | Ar |
| Aluminumgalliumindiumphosphide | TMAl, TEAl, TMGa, TEGa, | PH₃(Phosphino), | H_{2,} N_{2,} Ar |
| (AlGalnP) | Tmln (Trimethylindium) | TBP (Tertiarbutylphoshine) | |
| Galliumindiumphosphide | TMGa, EGa, TMln | Ph_{3,} TBP | H_{2,} N_{2,} Ar |
| ((GaLn)(P) | | | |
| Aluminumindiumphosphide | TMAl, EAl, TMln | PH_{3,} TBP | H_{2,} N_{2,} Ar |
| ((Alln)(P) | | | |
| Galliumindiumarsenidephosphide | TMGDa, TEGa, TMln | AsH₃, TBAs, PH_{3,} | H_{2,} N_{2,} Ar |
| (((Galn)(ASP)) | | TBP | |
| Aluminumgalliumindiumarsenidephosphide | TMAl, TEAl, TMGa, TEGa, | AsH₃, TBAs, PH_{3,} | H_{2,} N_{2,} Ar |
| (AlGaln) | TMln | TBP | |
| (AsP)) | | | |
| Aluminumnitride | TMAl, TEAl | NH₃ (Ammonia) | H_{2,} N_{2,} Ar |
| (Aln) | | | |
| Galliumnitride | TMGa, TEGa | NH₃ | H_{2,} N₂, Ar |
| (GaN) | | | |
| Indiumnitride | TMln | NH3 | H2, N_{2,}, |
| (InN) | | | Ar |
| Aluminumgalliumindiumnitride | TMAl, TEAl, TMGa, TEGa, | NH₃ | H_{2,} N₂, Ar |
| ((AlGaIn)(N) | TMln | | |
| Galliumindiumnitride((Galn)(N) | TMGa, TEGa, TMln | NH₃ | H_{2,} N_{2,} Ar |
| Galliumantimonide (GaSb) | TMGa, TEGa | TMSb (Trimethylantimony) | H_{2,} N_{2,} Ar |
| | | TESb | |
| | | (Triethylantimony) | |
| Aluminumantimonide (AlSb) | TMAl, TEAl | TMSb, TESb | H_{2,} N_{2,} Ar |
| Indiumantimonide (InSb) | TMln | TMSb, TESb | H_{2,} N_{2,} Ar |
| Aluminumindiumantimonide | TMAl, EAl, TMln | TMSb, TESb | H_{2,} N_{2,} Ar |
| (AlIn)Sb)) | | | |
| Galliumindiumantimonide | TMGa, TEGa, TMln | TMSb, TESb | H_{2,} N_{2,} Ar |
| ((GaIn)Sb)) | | | |
| Galliumarsenideantimonide | TMGa, TEGa | PH_{3,} TBP, TMSb, | H_{2,} N_{2,} Ar |
| (Ga(AsSb)) | | TESb | |
| Aluminumarsenideantimonide | TMAl, TEAl | AsH_{3,}TBAs, TMSb, | H_{2,} N_{2,} Ar |
| (Al(AsSb)) | | TESb | |
| Indiumarsenideantimonide | TMln | AsH_{3,}TBAs, TMSb, | H_{2,} N_{2,} Ar |
| (In(AsSb)) | | TESb | |
| Galliumindiumarsenideantimonide | TMGa, EGa, TMln | AsH_{3,} TBAs, TMSb, | H_{2,} N_{2,} Ar |
| (GaIn)(AsSb)) | | TESb | |
| Galliumphosphideantimonide | TMGa, TEGa | PH_{3,} TBP, TMSb, | H_{2,} N_{2,} Ar |
| (GaPSb)) | | TESb | |
| Indiumphosphideantimonide | TMln | PH_{3,} TBJP, TMSb, | H₂, N_{2,} Ar |
| (In(PSb)) | | TESb | |
| Indiumphosphidearsenideantimonide | TMln | PH_{3,} TBP, AsH_{3,} | H_{2,} N_{2,} Ar |
| (In(PAsSb)) | | TBAs, TMSb, TESb | |
| Cadmiumtelluride (CdTe) | DMCd (Dimethyl-cadmium) | DETe | H_{2,} N_{2,} Ar |
| | | Diethyltellurium) | |
| | | DMTe | |
| | | Dimethyltellurium, | |
| | | DlPe | |
| | | (Diisopropyltellurium) | |
| Mercurytelluride (Hg/Te) | Hg (Mercury) | DETe | H_{2,} N₂, Ar |
| Cadmiummercurytelludride | DMCd, HGD | DETe | H_{2,} N_{2,} Ar |
| ((CdHg)Te) | | | |
| Zincsulfide | DMZn (Dimethyl-zinc), | H₂S Hydrogensulfide, | H_{2,} N_{2,} Ar |
| (ZnS) | DEZn (Diethylzinc) | DES | |
| | | (Diethylsulfide), | |
| | | DTBS (Ditertbutylsulfide) | |
| Zincselenide(ZnSe) | DMZn (Dimethylzinc), DEZn | DMSe (Dimethylselenide), | H_{2,} N_{2,} Ar |
| | (Diethylzinc) | DESe | |
| | | Diethylsselenium, | |
| | | DlPSe(Diisopropylselenium), | |
| | | DTBSe | |
| | | (Ditertbutylsselenium) | |
| Bariumstrontiumtitanate | Ba(thd)₂, | O₂ (Oxygen), O₃ | N_{2,} Ar |
| ((BaSr)TlO₃) | (Barium/Strontiumtetramethylheptanedionat), | (Ozone), N₂O | |
| | Ba(hfa)₂ | (laughing gas) | |
| | (Barium//Strontiumhexafluoroaetylacetone), | | |
| | TIP | | |
| | (Titaniumtetrakisisopropoxide), | | |
| | TTB | | |
| | (Titaniumetrakisterbutoxide), | | |
| leadzirconatetitanate | TEL (Tetraethyllead), | O₂ | |
| (Pb(ZrTi)O₃) | TEL | | |
| | (Tetraphenyllead Pb(thd)₂ | | |
| | (Leadtetramethylheptanedionate), | | |
| | ZlP | | |
| | (Zirconiumtetrakisisopropoxide) | | |
| | TIP, TTB | | |

1. A method of depositing compounds on a substrate by means of a metal organic gas phase deposition and a first mixture of at least one carrier gas and at least one metal organic and a second mixture of at least one carrier gas and at least one Group V compound or Group VI compound whereby both mixtures are separately fed into a MOCVD apparatus, characterized in that the first mixture of at least one carrier gas and at least one metal organic is fed into the apparatus between the substrate and the second mixture of at least one carrier gas and at least one Group V compound or Group VI compound.

2. The method according to the preceding claim, characterized in that for the first mixture at least one Group II compound is selected as the metal organic.

3. The method according to claim 1, characterized by dimethylzinc as the metal organic.

4. The method according to claim 1, characterized by (Ba, Sr) compounds as metal organics.

5. The method according to claim 1, characterized in that for the first mixture at least one Group III compound is selected as the metal organic.

6. The method according to claim 1, characterized by trimethylgallium and/or trimethylaluminum and/or trimethylindium as metal organics.

7. The method according to claim 1, characterized in that for the first mixture at least one Group IV compound is selected as the metal organic.

8. The method according to claim 1, characterized by titaniumisopropoxide as the metal organic.

9. The method according to claim 1, characterized in that AsH₃ and/or PH₃ and/or NH₃ is selected as the Group V compound.

10. The method according to claim 1, characterized in that oxygen or diethyltellurium is selected as the Group VI compound.

11. The method according to claim 1, characterized in that III/V compounds and/or II-VI compounds are deposited.

12. The method according to claim 1, characterized in that GaN, AlN or InN or alloys of these compounds are deposited.

13. The method according to claim 1, characterized in that an oxide, especially (Ba, Sr) titanate is deposited.

14. The method according to claim 1, characterized in that hydrogen and/or nitrogen and/or argon is used as the carrier gas.

15. A MOCVD apparatus for gas phase deposition with at least two gas inlets (4, 5), characterized by means for flexibly introducing gases into the apparatus.

16. The MOCVD apparatus according to claim 15 characterized in that between the gas inlets (4, 5) and the supply vessels for the gases to be fed into the apparatus, gas collecting lines (51, 52, 53) are provided in which there are arranged at least two valves (V1, V2, V3).

17. The method according to claim 1 characterized in that the substrate is selected from SiC, sapphire, silicon, InP (indiumphosphide), InAs (indiumarsenide), GaAs (galliumarsenide), GaN (galliumnitride), AlN (aluminumnitride), GaSb (galliumantimonide) and/or GaP (galliumphosphide).
